(19) United States
(12) Patent Application Publication
(10) Pub. No.: US 2021/0273363 A1
(43) Pub. Date: Sep. 2, 2021

(54) Electrical Connector

(71) Applicant: Bare Conductive Ltd, London (GB)

(72) Inventors: Stefan Dzisiewski-Smith, London (GB); Owen Hissey, London (GB); Bibiana Nelson, London (GB)

(21) Appl. No.: 17/255,089

(22) PCT Filed: Jun. 28, 2019
(86) PCT No.: PCT/GB2019/051844

§ 371 Date: Dec. 22, 2020

(30) Foreign Application Priority Data
Jun. 28, 2018 (GB) 1810670.8
Jul. 25, 2018 (GB) 1812109.5

(51) Int. Cl. H01R 12/88; H01R 12/71; H01R 12/79; H01R 12/87

(52) U.S. Cl. CPC H01R 12/88; H01R 12/87; H01R 12/79; H01R 12/714

(57) ABSTRACT

An electrical connector system for providing an electrical connection between a first electrode and a second electrode printed onto a substrate. The system comprises a male connector comprising the first electrode located proximal to a first end of the male connector and a female connector comprising a coupling portion forming a cavity with an opening into which the first end of the male connector may be received, the coupling portion having one or more biasing surfaces that each oppose a base of the female connector. The electrical connector system is configured such that when the male connector is urged into the coupling portion, the first electrode is urged towards the base of the female connector by the one or more biasing surfaces to form an electrical connection between the first electrode and the second electrode positioned between the base and the first end of the male connector.

### TECHNICAL FIELD

The present disclosure relates to electrical connectors. In particular, but without limitation, this disclosure relates to electrical connectors for connecting to electrodes printed on substrates, such as flexible substrates.

### BACKGROUND

Electrical connectors, generally, attempt to provide an electrical connection between two contacts or electrodes. Some electrical connectors include “male” and “female” connectors. A male connector is generally a component that is received within a corresponding female connector. Female connector generally has an internal cavity for receiving the male connector. The two parts may be generally configured such that the male connector may be secured within the female connector, thereby providing an electrical and mechanical connection between the two parts.

Generally, in use, the electrodes of the two parts may be urged together to ensure a reliable and consistent electrical connection. This may be achieved through providing sprung contacts. Sprung contacts may be resilient contacts, or contacts located on a resilient support structure, that may be displaced when the two parts are connected and are therefore urged against the opposing contact to maintain electrical connection.

Sprung contacts are, however, more complicated and expensive to manufacture, and more liable to being broken when compared to non-resilient or sprung contacts. For instance, to provide resilience, sprung contacts tend to be made of shaped metal that can be fixed within the connector. This means that such contacts cannot be manufactured via printing onto a substrate, such as in printed electronics (e.g. conductive ink) or etching away layers of a substrate, such as in printed circuits (e.g. etched PBCs).

Recent developments in printed electronics allow electronic circuits to be formed quickly and inexpensively, for instance by printing using conductive ink. Such circuits may be printed onto not only rigid substrates but also flexible substrates (for instance, paper or cardboard). This allows inexpensive, disposable circuits to be manufactured.

Having said this, such circuits can be difficult to connect to as the contacts on such circuits will inherently be non-resilient. Furthermore, contacts printed using conductive ink may be prone to being worn off of the substrate if repeatedly connected and disconnected. Equally, flexible substrates may be prone to buckling as they are inserted into a connector.

There is therefore a need for a simple and effective method for connecting to flat, non-resilient contacts, such as those printed onto a substrate.

### SUMMARY

According to a first aspect there is provided an electrical connector system for providing an electrical connection between a first electrode and a second electrode printed onto a substrate, the system comprising a male connector comprising the first electrode located proximal to a first end of the male connector and a female connector comprising a coupling portion forming a cavity with an opening into which the first end of the male connector may be received, the coupling portion having one or more biasing surfaces that each oppose a base of the female connector. The electrical connector system is configured such that when the male connector is urged into the coupling portion, the first electrode is urged towards the base of the female connector by the one or more biasing surfaces to form an electrical connection between the first electrode and the second electrode positioned between the base and the first end of the male connector.

Accordingly, embodiments of the invention provide a simple and effective method of mechanically and electrically connecting to a printed electrode. The electrode may either be printed onto a substrate that can be inserted between the base and the first electrode, or the electrode may be printed onto the base itself.

The system comprises two separate parts, a first part (male connector) and second part (female connector). The descriptors “male” and “female” relate to how the male connector is received within the female connector, and do not necessarily relate in any way to the direction of power/electricity transfer.

The coupling portion may comprise one or more receiving means that may be in the form of one or more jaws. The one or more biasing surfaces need not directly oppose the base of the female connector as there may be a transverse displacement between the base and the one or more biasing surfaces. The one or more biasing surfaces oppose the base in that they face towards the plane along which the base lies (and vice versa).

According to an embodiment each of the one or more biasing surfaces is angled relative to the base such that the internal height of the cavity decreases from the opening towards a rear portion of the cavity. This provides the means for at least some of the biasing force to clamp the first against the second electrode as the male connector is urged into the cavity. The biasing surface angle need not be straight, but could be curved, provided that the internal height of the cavity decreases. The angled biasing surface may form the cavity at least partly into a wedge-shape.

According to an embodiment the female connector comprises a substrate receiving section configured to receive the substrate upon which the second electrode is printed and wherein the system is configured to clamp the substrate between the base and the first electrode when the male connector is urged into the coupling portion.

According to an embodiment the receiving section comprises a substrate holder that is configured to receive and hold the substrate in an interference fit prior to the male connector being received into the female connector. The substrate holder may have an internal height that is less than the thickness of the substrate to enable the interference fit. The interference fit may be between an upper lip of the substrate holder and the base of the female connector.

The base may slope downwards (may decrease in thickness) from an entrance to substrate holder. This can help guide the substrate into position.

According to an embodiment the second electrode is incorporated into a flexible strip for insertion between the base and the first electrode. Accordingly, the system may be configured to connect to an electrode printed onto a flexible substrate. Such an electrode cannot provide its own biasing force. The clamping force provided by the system therefore enables a secure connection to the flexible substrate. Furthermore, where the clamping force is provided by a rotational motion, as shall be described later, the rotational motion can avoid the flexible substrate from buckling.

According to an embodiment the base forms part of the substrate and the second electrode is printed onto the base. Accordingly, the second electrode may be integrated into the female connector.

According to a further embodiment the coupling portion is resilient and configured to be deflected at least partially when the first end is urged into the coupling portion thereby urging the first electrode against the base of the female connector. This provides additional clamping action to provide an improved connection.

According to an embodiment the female connector comprises a releasable locking mechanism configured to releasably secure the male connector into position in the female connector once the male connector has been urged into the coupling portion to secure the first electrode against the second electrode.

According to an embodiment, for at least a portion of the cavity, the internal height of the cavity is less than a thickness of the first end of the male connector.

According to an embodiment the female connector comprises housing including a wall that opposes the coupling portion, wherein a distance between the coupling portion and the wall is substantially the same as a length of the male connector from the first end of the male connector to a second end of the male connector that is opposite to the first end, and wherein the system is configured such that the first electrode is urged towards the base of the female connector in response to the first end of the male connector being inserted into the coupling portion at an angle to the base of the female connector and being rotated towards the base of the female connector.

The rotational action reduces wear on the electrodes and, where the substrate is a flexible substrate, avoids the substrate buckling as the male connector is urged into the female connector. The wall of the housing provides resistance against the male connector leaving the cavity once fully inserted. Accordingly, the wall at least partly secures the male connector in place. The male connector may fit between the wall and the coupling portion by means of an interference fit.

According to an embodiment the male connector comprises a sloped rear wall located at the second end of the male connector and configured to contact the wall of the female connector when the male connector is rotated towards the base of the female connector to urge the male connector further into the coupling portion. The first electrode may be located on a base, or underside, of the male connector and the sloped rear wall may form an obtuse angle with the base of the male connector. The sloped wall allows the male connector to be urged gradually further into the coupling portion as it is rotated. Furthermore, the sloped wall provides some clearance to allow the second end of the male connector to pass the top of the wall as the male connector is rotated into position.

According to an embodiment the first electrode of the male connector may comprise two surfaces joined by an edge that is configured to contact the second electrode as the male connector is urged into the coupling portion. The edge may slide along the second electrode as the male connector is rotated towards the base. The first electrode may form a contact around the edge of a rigid substrate of the male connector.

According to an embodiment the first electrode is formed on a printed circuit board (PCB) housed within the male connector and exposed at least at the first electrode. The male connector may therefore provide housing support for the PCB to avoid the PCB from breaking as the two electrodes are urged together. The first electrode may form a contact around the edge of the PCB. The system has the advantage that two flat, non-sprung (non-resilient) electrodes may be connected together simply via a connection system that is easy to use and simple and inexpensive to manufacture.

The male connector may comprise a plurality of first electrodes formed on the printed circuit board, proximal to the first end of the male connector, wherein solder resist is removed from between the contacts to improve connection with one or more corresponding second electrodes positioned between the base and the first end of the male connector. This avoids the risk of the solder resist protruding above the first and preventing contact with the one or more second electrodes.

According to an embodiment the male connector comprises one or more indentations for receiving one or more protrusions from the coupling portion. This helps guide the male connector into place and provides one or more pivot points about which the male connector may be rotated. Each of the one or more indentations may have a base the slops downwards, towards the first end of the male connector. This profile may match the sloping of the one or more biasing surfaces.

According to an aspect there is provided a male connector as defined herein and configured for use in an electrical connector system as defined herein. The male connector may comprise a first electrode located proximal to a first end of the male connector.

According to an embodiment the electrode is located on a base of the male connector and wherein the male connector further comprises a sloped rear wall located at a second end of the male connector that is opposite to the first end, the sloped rear wall forming an obtuse angle with the base of the male connector.

The rear wall may be configured to contact the (rear) wall of the female connector when the male connector is rotated towards the base of the female connector to urge the male connector further into the coupling portion.

According to an embodiment the male connector comprises an upper side, opposite to the base, wherein one or more indents are formed at the first end of the upper side and are configured to engage with one or more protrusions from a corresponding female connector into which the male connector is configured to be inserted. Each protrusion may be a tip or end of the lip of a cavity into which the male connector may be urged. According to an embodiment the base of each of the one or more indentations slopes downwards towards the first end of the male connector.

According to an embodiment the first electrode of the male connector comprises two surfaces joined by an edge.

According to an embodiment the first electrode is connected to circuitry formed on a printed circuit board housed within the male connector and exposed at least at the first electrode.

According to an embodiment the male connector comprises a plurality of first electrodes formed on the printed circuit board, proximal to the first end of the male connector, wherein solder resist is removed from between the contacts to improve connection with one or more corresponding second electrodes positioned between the base and the first end of the male connector.

According to an aspect there is provided a female connector as defined herein and configured for use in an electrical connector system as defined herein.

Further embodiments are described below.

According to a first embodiment there is provided an electrical connector system for connecting to an electrode printed onto a substrate, the system comprising a first part comprising a first electrode located proximal to a first end of the first part; and a second part comprising one or more receiving means, each forming a cavity with an opening into which the first end of the first part may be received, each of the one or more receiving means having a biasing surface that opposes a base of the second part, the biasing surface being angled relative to the base such that the internal height of the cavity decreases from the opening towards a rear portion of the cavity. The electrical connector system is configured such that when the first part is urged into the one or more receiving means, the first electrode is urged towards the base of the second part by the one or more biasing surfaces to form an electrical connection between the first electrode and a second electrode positioned between the base and the first end of the first part, the second electrode being printed onto a substrate.

The substrate may form part of the electrical connector system, or may be an external part that is inserted into the electrical connector system. For instance, the electrode may be printed directly onto the base of the second part of the electrical connector system. That is, the substrate may comprise the base or vice versa.

The electrical connector system may be for connecting to a flat, non-sprung electrode such as one printed or otherwise deposited onto flexible substrate.

Alternatively, the substrate may be secured within the electrical connector system between the first and second parts, e.g. via a pinning or clamping action.

The receiving means may be one or more jaws or may be one or more cavities formed within one or more walls, or otherwise.

The biasing surface of the receiving means need not directly oppose the base, for instance, the biasing surface and base may be vertically separated and horizontally separated from each other.

According to an embodiment the second part comprises a substrate receiving section configured to receive the substrate and wherein the system is configured to secure the substrate against the base when the first part is urged into the one or more receiving means.

According to an embodiment the receiving section comprises a substrate holder that is configured to that receive the substrate in an interference fit prior to the second part being fitted into the first part.

According to an embodiment the system is configured to connect to an electrode printed onto a flexible substrate.

According to an embodiment the second electrode is be incorporated into a flexible strip for insertion between the base and the first electrode.

According to an embodiment the base forms part of the substrate and wherein the second electrode is printed onto the base.

According to an embodiment each of the one or more receiving means is resilient and configured to be deflected at least partially when the first end is urged into the one or more receiving means thereby urging the first electrode against the base of the second part.

The resilience can provide a securing/connecting force to pin/clamp/squeeze the first connector against the second connector. The receiving means may be jaws. The one or more jaws may be resilient. This allows the one or more jaws to flex as the first end is urged into the jaw, thereby urging the first portion against the second portion. Having said this, the receiving means need not be resilient, and could instead be rigid.

According to an embodiment, for each of the one or more receiving means, the cavity is formed as a wedge-shaped cavity.

According to an embodiment the second part comprises a releasable locking mechanism configured to releasably secure the first part into position on the second part once the first part has been urged into the one or more receiving means to secure the first contact against the second contact.

According to an embodiment the second part comprises housing including a wall that opposes the one or more receiving means, wherein a distance between the one or more receiving means and the wall is substantially the same as a length of the first part from the first end of the first part to a second end of the first part, and wherein the system is configured such that the first electrode is urged towards the base of the second part in response to the first end of the first part being inserted into the one or more receiving means at an angle to the base of the second part and being rotated towards the base of the second part.

According to an embodiment the first electrode of the first part comprises two surfaces joined by an edge.

According to an embodiment the first electrode forms a contact around the edge of a rigid substrate of the first part.

According to an embodiment the rigid substrate is a circuit board housed within the first part and exposed at least at the first electrode.

According to an embodiment the first part one or more indentations corresponding to the one or more receiving means, the one or more indentations being configured to receive at least part of a corresponding receiving means.

Urging the first part into the one or more receiving means may comprise inserting the first end of the first part into the one or more receiving means at an angle to the surface of the second part, and rotating the first part towards the surface of the second part.

The first part may comprise a casing for electronic components connected to the first electrode. The casing may be mechanically secured to the second part via an interference fit between the one or more jaws and an opposing structure (e.g. an opposing wall) or a catch/latch mechanism.

The first part may have a sloped wall proximal to a second end that is opposite to the first end, the sloped wall being configured such that the first part is urged into the one or more jaws as the second end is rotated/urged against an opposing wall/member of the second part, the opposing wall/member opposing the one or more jaws.

The first part may have one or more indentations for receiving the one or more receiving means/jaws. Each indentation may be sloped similarly to the corresponding biasing surface. Accordingly, the one or more indentations may have sloped walls and may be configured to urge the first end towards the surface of the second part as the first end is urged into the jaws/as the one or more sloped walls of the one or more indentations are urged against the corresponding one or more jaws.

The first end of first part may comprise a protrusion comprising the first electrode. The first electrode may be formed over a corner/edge of the protrusion.

The first part may comprise a plurality of electrodes. Equally, the substrate may comprise a plurality of electrodes.

The inner and outer containers may be considered “shoes” with the inner shoe being received within the outer shoe.

### BRIEF DESCRIPTION OF THE DRAWINGS

Arrangements of the present invention will be understood and appreciated more fully from the following detailed description, made by way of example only and taken in conjunction with drawings in which:

FIG. 1 shows a connector system according to an embodiment in assembled form;

FIG. 1B shows a top-down view of the inside of the outer housing of FIG. 1A;

FIG. 2 shows cross-sectional, underside, side, top, front and rear views of the outer housing of FIG. 1A;

FIG. 3 shows the inner housing of FIG. 1A via cross-sectional, underside, side, top, front and rear views;

FIG. 4 shows a perspective view and front and side cross-sectional views of the contacts of the PCB mounted within the inner housing of FIG. 1A;

FIG. 5 shows a top-down view of the outer housing and substrate both before (top) and after (bottom) the substrate has been inserted into the outer housing;

FIGS. 5 and 6 show how the inner housing may be mounted within the outer housing to provide a mechanical and electrical connection between the contacts of the inner housing and the contacts of the substrate; and

FIGS. 8 and 9 show magnified cross-sectional views of the inner and outer housings as the system is rotated closed.

### DETAILED DESCRIPTION

The general function of various embodiments shall be described first before specific embodiments are described with reference to the figures.

According to an embodiment the connector system comprises a first part (an inner container or housing) that is configured to receive a second part (an outer container or housing) and a substrate having an electrode on it. The inner container may be received in the outer container. The substrate may be inserted into a substrate holder in the inner container. The substrate may be held in the substrate holder via an interference fit.

The inner container has an electrode at a first end of the inner container. The inner container has an electrode at a first end of the inner container. The outer container has at receiving means in the form of two jaws. The two jaws are configured to receive the first end. The substrate holder is located on a base of the outer container, in between the two jaws.

The inner container may be a PCB holder that contains a PCB or any other form of electronic circuitry. The electrode on the PCB holder allows an electrical connection to be made between the electrode on the substrate and the electronic circuitry.

When inserted into the substrate holder the substrate may be pinned to the base of the outer container by the electrode of the inner container. That is, as the inner container is urged or pushed into the receiving means, the electrode of the inner container is urged against the electrode of the substrate to form electrical connection and to mechanically secure the substrate in position by pinning the substrate against the base.

The electrical connector system may work via a pivoting motion. The inner container may be inserted into the jaws at an angle to the base and then rotated towards the base of the outer container. The jaws have a sloped internal upper face that opposes the base of the outer container. As the inner container rotates towards the base of the outer container, the electrode of the inner container is moved towards the electrode of the substrate and urged against the electrode of the substrate to pin the substrate against the base of the outer container.

An opposing wall is located opposite the jaws of the outer container. The inner container has a sloped base that ensures that as the inner container is rotated towards the base of the outer container, the sloped base is urged against the opposing wall and the opposing wall thereby urges the inner container further into the jaws of the outer container.

The inner container may be secured into position within the housing of the outer container by releasable locking mechanism that may be released, for instance, via the use of a key.

The electrode on the substrate may be printed onto the substrate via electronic ink. Further tracks of electronic ink may be formed on the exposed surface of the substrate to act as a sensor, for instance a pest sensor. For instance, dropping from a pest, such as a bedbug, may be detected by a short circuit between the tracks.

The pivoting action for connecting to the printed substrate reduces the wear on the substrate thereby reducing the risk of rubbing away electronic ink from the surface of the substrate over repeated uses.

The electrode of the inner container may be printed around the edge and side of a board (such as the PCB) to improve contact at the board edge and to allow a good contact via the rotational camming action. The PCB may be secured to the inside of the inner container.

Whilst the above embodiments describe a connector system for connecting to the flexible substrate, the substrate may equally be rigid. Furthermore the substrate may not necessarily be received into the outer container, instead outer container may be attached to or form part of the substrate.

For instance, an electrode may be printed directly onto the base of the outer container, with the outer container acting as a means for connecting the electrode of the inner container to the electrode of the outer container.

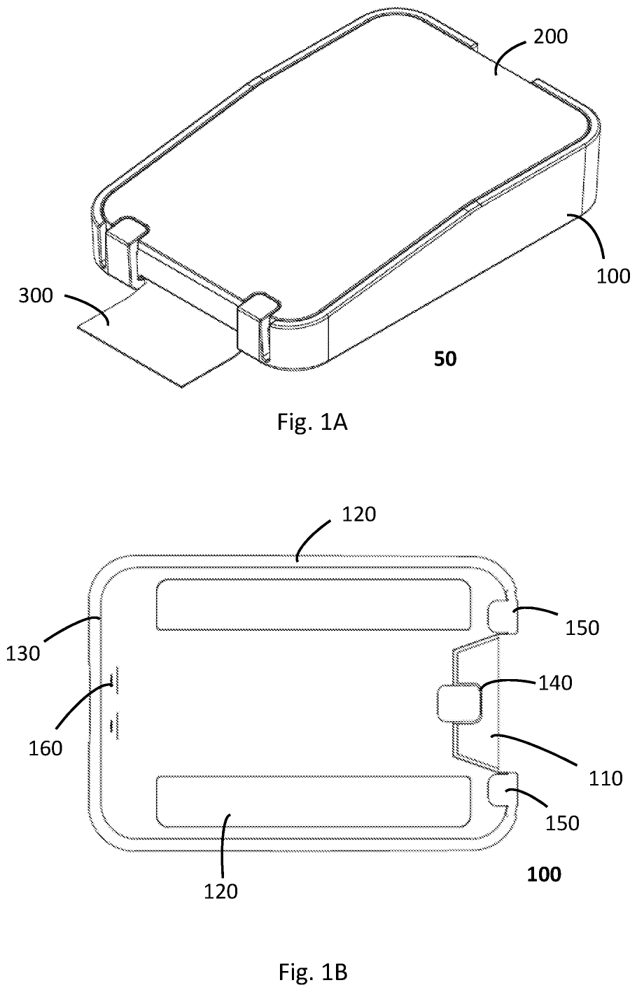

FIG. 1A shows an electrical connector system 50 according to an embodiment in assembled form. The electrical connector system 50 comprises an outer housing 100 and an inner housing 200.

The electrical connector system 50 is configured to mechanically and electrically connect to a substrate 300. The inner housing 200 is configured to be received within the outer housing 100. The interaction between the inner housing 200 and outer housing 100 causes the substrate 300 to be secured within the system 50.

The inner housing 200 comprises at least one electrode that is urged against an electrode on the substrate 300 when the inner housing 200 is received within the outer housing 100.

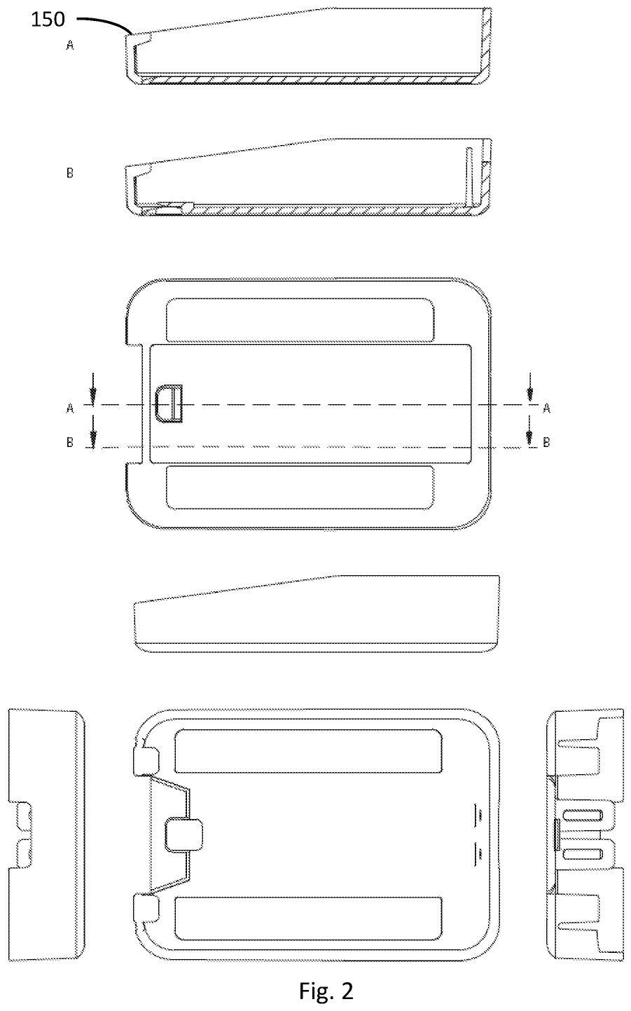

FIG. 1B shows a top-down view of the inside of the outer housing 100 of FIG. 1A. Furthermore, FIG. 2 shows cross-sectional, underside, side, top, front and rear views of the outer housing of FIG. 1A. The planes through which the cross sections are taken are indicated via dashed lines A and B.

The outer housing 100 comprises a flat base 110, opposing sidewalls 120 and a rear wall 130. The sidewalls 120 and rear wall 130 protrude from the edges of the base 110, perpendicular to the base 110. The sidewalls 120 are located along longitudinal edges of the base 110 and the rear wall 130 is located on a transverse edge at a rear, or distal, end of the outer housing 100. Each side wall 120 is connected to the rear wall 130 at corresponding corners. The base 110, sidewalls 120 and rear wall 130 form a cavity into which the inner housing 100 may be received. The base 110 has two longitudinal cutouts that run along the length of the outer housing 100, adjacent to the sidewalls 110, and spaced away from the central longitudinal axis of the outer housing 100.

A coupling section is located at a forward, or proximal, end of the outer housing 100 (at an opposite end to the rear end). The coupling section comprises a substrate holder 140 and two jaws 150 that protrude from the base 110 of the outer housing 100, perpendicular to the base 110. The jaws are spaced apart forming an opening such that the substrate 300 may be inserted between the jaws 115, into the substrate holder 140.

The substrate holder 140 forms a cavity into which the substrate 300 may be received and secured within the substrate holder 140 by means of an interference fit between the substrate holder 140 and the base 110.

The jaws 150 are means for receiving and securing the inner housing 200 against a substrate received within the substrate holder 140. The jaws 150 form a cavity into which the front end of the inner housing 200 may be received. Each jaw has a sloped upper face that opposes the base 110 of the outer housing 100. The sloped upper face means that the internal height of each jaw 115 decreases from an entrance of the jaw 115 back to the rear of the jaw 115.

The decreasing internal height of the jaws 115 serves to urge the front of the inner housing 200 downwards, against the base 110 of the outer housing 100, when the front of the inner housing 200 is urged into the jaws 115. This provides a clamping force that serves to ensure that there is a strong connection between the contacts of the inner housing 200 and the contacts of the substrate 300. Furthermore, this clamping action serves to secure the substrate 300 within the connector system 50.

A locking mechanism 160 protrudes from the base 110 towards the rear end of the base 110. The locking mechanism 160 is configured to releasably engage with a corresponding locking mechanism in the inner housing 200 to lock the inner housing 200 in place within the outer housing 100 when the inner housing 100 is fully inserted into the outer housing 100.

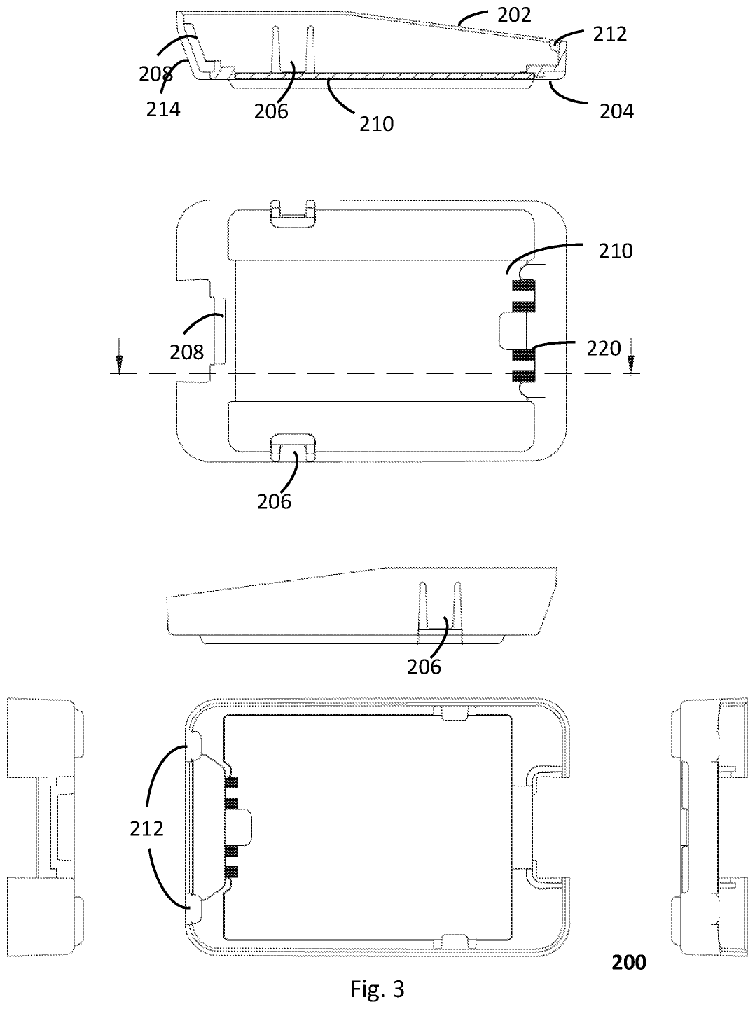

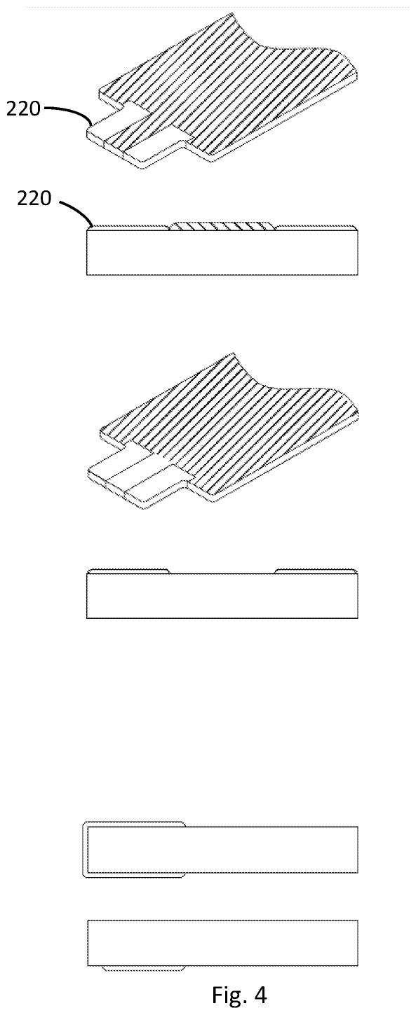

FIG. 3 shows the inner housing 200 of FIG. 1A via cross-sectional, underside, side, top, front and rear views. The plane through which the cross section is taken is indicated via a dashed line.

The inner housing 200 comprises a casing that is formed of two parts, an upper part 202 (or lid) and a lower part 204. These form a case or housing for a printed circuit board (PCB) 210. The inner housing 200 is therefore a PCB holder. The front, rear and top views (the bottom three views) show only the lower part 204 of the inner housing 200. Accordingly, the PCB can be seen in the top view, although this would be covered once the upper part 202 was secured over the top of the lower part 204.

The lower part 204 forms a cavity into which the PCB 210 may be lowered to lie flat on a base of the lower part 204. The PCB 210 can be secured in place via clips 206 located in sidewalls of the lower part 204. Each clip 206 protrudes into the cavity and is resilient such that it may be displaced outwards as the PCB 210 is inserted into the cavity. Once the PCB 210 is fully inserted, such that it lies flat against the base of the lower part 204, the clips 206 spring back into their original position to lock the PCB 210 into place. Each clip 206 can therefore be considered a latch.

The PCB 210 sits within a recess in the base of the lower part 204 to prevent the PCB 210 from moving around once locked into position. Once the PCB 210 is secured within the lower part 204, the upper part 202 may be locked into position over the lower part 204 to enclose the PCB 210. A clip is provided at the rear of the upper part 202 for engaging with the lower part 204 to lock the upper part 202 in place on the lower part 204.

The base of the lower part 202 comprises a cutout for exposing a portion of the underside of the PCB 210 when the PCB is secured within the inner housing 200.

The PCB 210 comprises contacts 220 (or electrodes) on the underside of the PCB 210 at a proximal (near) edge of the PCB 210. The contacts 220 are located on rectangular tabs protruding from the proximal edge of the PCB 210, in the plane of the PCB 210. Two contacts 220 are located on each of the two tabs. The inner housing 200 encases the PCB 220 with the exception of the cutout on the underside of the inner housing 210 which exposes the PCB 220, and in particular exposes the contacts 220. The tabs of the PCB 220 slot underneath the underside of the lower part 204. This provides support for the contacts 220 when urged against the contacts of the substrate 300.

The lower part 204 comprises a locking mechanism 208 that is configured to engage with a corresponding locking mechanism 160 of the outer housing 100 to lock the inner housing 200 in place within the outer housing 100.

Two recesses 212 are located at upper front edge of the inner housing 200, that is, at the proximal end of the inner housing 200 on the top of the inner housing 200. The recesses are arranged such that the jaws 150 of the outer housing 100 may be received within, and engage with, the recesses 212. Each recess 212 has a lower surface that slopes downwards towards the proximal end of the inner housing 200. That is, the depth of each recess 212 increases towards the proximal end of the inner housing 200.

The lower part 204 comprises a rear wall 214 that is located at the distal end of the lower parts 204, that is, at the opposite end to the two recesses 212. The rear wall 214 slopes outwards from the base of the lower part 210. The sloping of the rear wall 214 provides a means for urging the inner housing 200 forward, against the jaws 115 of the outer housing 100, when the inner housing 200 is inserted into the outer housing 100.

FIG. 4 shows a perspective view and front and side cross-sectional views of the contacts of the PCB 220 mounted within the inner housing 200 of FIG. 1A.

As discussed with reference to FIG. 3, the contacts 220 are located on tabs that protrude from the end of the PCB 210. Two contacts 220 are located on each tab.

In the present embodiment the contacts 220 are exposed by etching away a solder resist (shown with cross-hatching in FIG. 4) that forms an upper resistive layer. To ensure an effective connection between the contacts 220 of the PCB 210 and the contacts 310 of the substrate 300, the solder resist between the contacts 220 is also etched away. This can be seen in the middle cross-sectional view shown in FIG. 4. Removing solder resist from between the contacts 220 provides an improved connection as there is no chance of solder resist rising above the contacts 220 and preventing connection with the contacts 310 on the substrate 300.

To further improve the connection, the contacts 220 are wrapped around the edge of the PCB 210. Each contact 220 wraps around the front and side faces of the respective tab, and around to the underside of the tab (see bottom of FIG. 4). Edge plating around the side of the PCB 210 helps in two ways. Firstly, it ensures that the conductive electrode extends all the way to the edge of the PCB 210, improving contact by having no “dead” zone at the board edge that may contact the substrate 300 first and impede contact with the conductive electrode. Secondly, if the connection is made by rotationally “camming down” onto the substrate 300, then it creates a conductive corner which is locally sharp and ensures good contact.

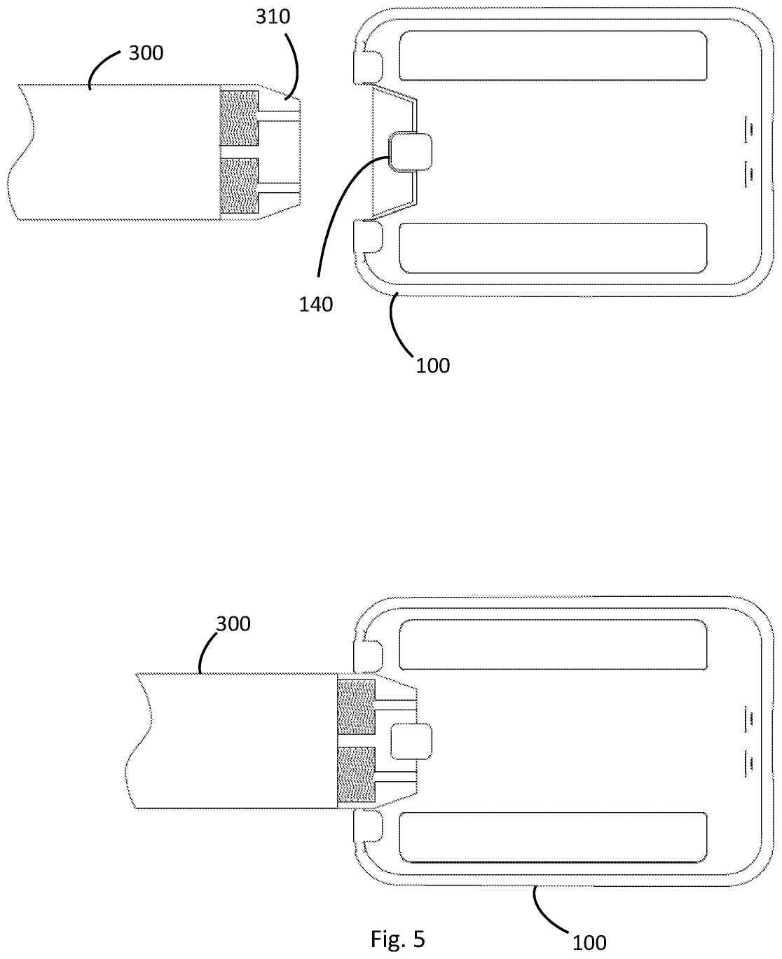

FIG. 5 shows a top-down view of the outer housing 100 and substrate 300 both before (top) and after (bottom) the substrate 300 has been inserted into the outer housing 100.

The substrate 300 has contacts printed onto one side of a proximal end of the substrate 300. The contacts 310 may be formed from conductive ink printed onto the substrate 300. Alternatively, the contacts may form part of the substrate 300 and may be exposed via etching. The contacts 310 may be connected to interwoven or interdigitated conductive tracks for the detection of pests. For instance, a pest may be detected when the tracks are short-circuited via droppings from the pest. In FIG. 5 the tracks are hidden by a cover; however, in use, the tracks would be exposed.

The substrate 300 may be flexible and may be manufactured using inexpensive materials. This means that the substrate may be cut down to size to fit a particular use case and may be discarded and replaced relatively inexpensively. In the present embodiment the substrate 300 is made from card.

To secure the substrate 300 within the connector system 50, the substrate 300 is first inserted into the substrate holder 140. This happens when the outer housing 100 has been separated from the inner housing 200. That is, this occurs before the inner housing 200 is mounted within the outer housing 100.

The base 110 of the outer housing 100 becomes thinner towards the proximal edge of the outer housing 100. This forms a ramp that leads to the substrate holder 140 to help guide the substrate 300 into the substrate holder 140.

The substrate holder 140 is raised jaw that has an internal height that is smaller than the thickness of the substrate 300. The substrate holder 140 holds the substrate 300 in place via an interference fit. That is, the substrate holder 140 urges the substrate 300 against the base 110 of the outer housing 100. The base 110 is cut away underneath the substrate holder 140 to allow the substrate 300 to flex downwards when the substrate 300 is inserted into the substrate holder 140.

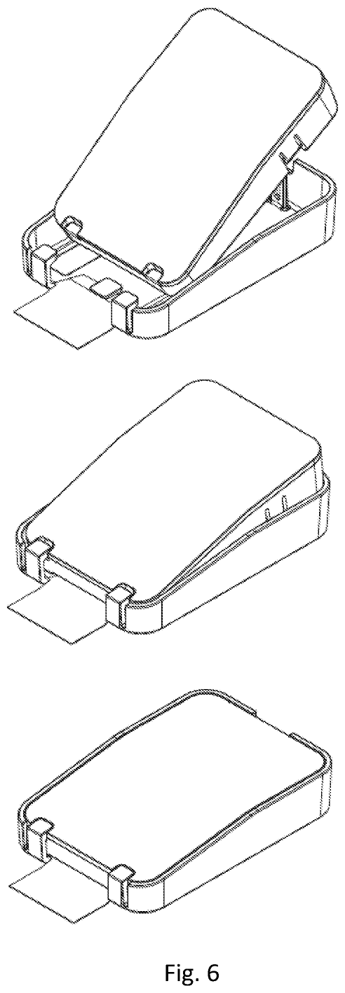

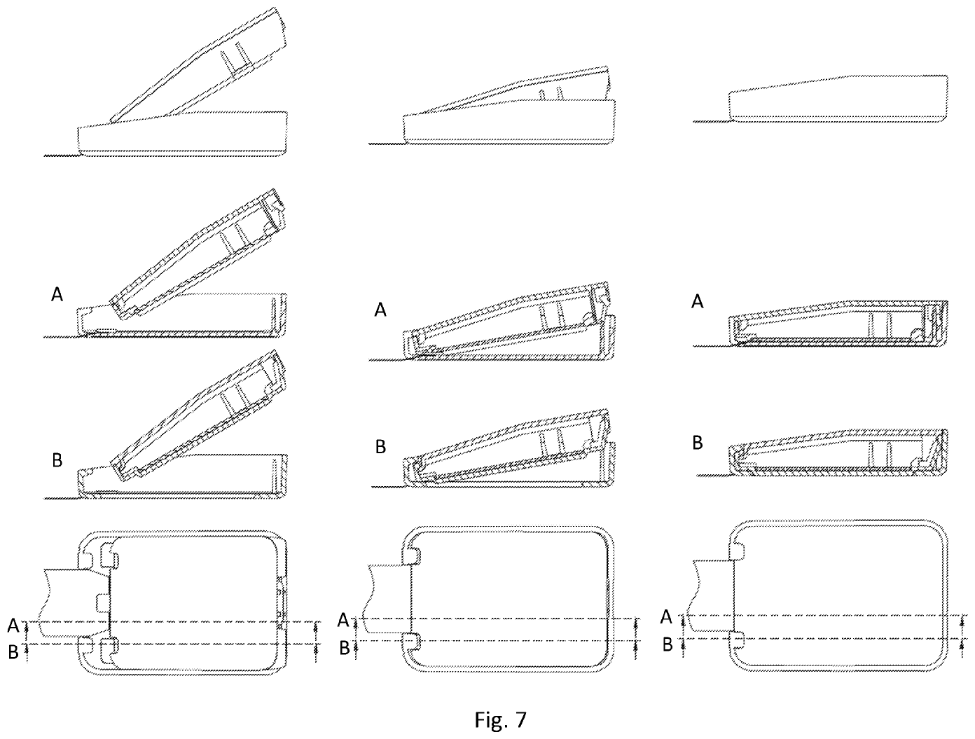

FIGS. 5 and 6 show how the inner housing 100 may be mounted within the outer housing 200 to provide a mechanical and electrical connection between the contacts 220 of the inner housing 100 and the contacts 310 of the substrate 300.

The substrate 300 is mechanically secured within the system 50 and electrically connected to the system 50 via a pinching or pinning action. The pinching action is provided as the inner housing 200 is urged into the jaws 150 outer housing 100 at an angle and rotated into position flat against the base of the outer housing 100.

As shown at the top of FIG. 6, the proximal end of the inner housing 200 is inserted into the jaws 150 of the outer housing 100 when the substrate 300 is held in the substrate holder 140. Inner housing 200 is inserted into the jaws 150 at an angle to the base 110 of the outer housing 100. The tip of each jaw 150 is received within a corresponding recess 212 in the top edge of the inner housing 200.

The pinching action caused by the system allows the electrical connector system 50 to connect to a flat, non-sprung (non-resilient) electrode such as one printed on to a flat substrate. Furthermore, the rotating action avoids wear on the electrodes through repeated opening and closing of the system 50. In addition, the rotating and pinching action allows the system 50 to connect to an electrode on a flexible substrate without risking the substrate buckling as the system 50 is closed.

As can be seen in FIG. 7, the sloped rear wall 214 of the inner housing 200 provides a means for urging the front of the inner housing 200 further into the jaws 115 as the inner housing 200 is rotated into the outer housing 100. This is via the sloped rear wall 214 of the inner housing 200 contacting the rear wall 130 of the outer housing 100. Accordingly, as the inner housing 200 is rotated into the outer housing 100, the front of the inner housing 200 is urged further into the jaws 115 as the rear wall 130 of the outer housing 100 slides up the sloped rear wall 214 of the inner housing 200. The inner housing 200 is at least partially secured within the outer housing 100 via an interference fit between the jaws 115 and the rear wall 130 of the outer housing 100.

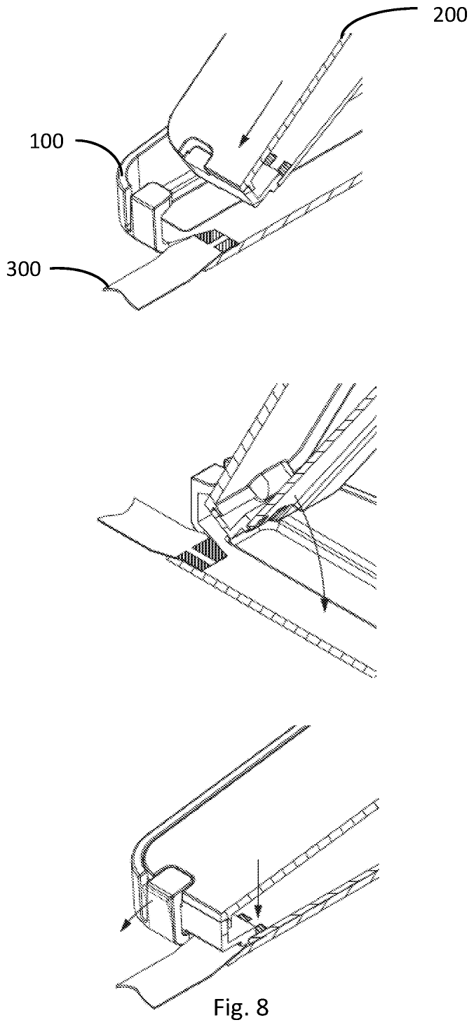

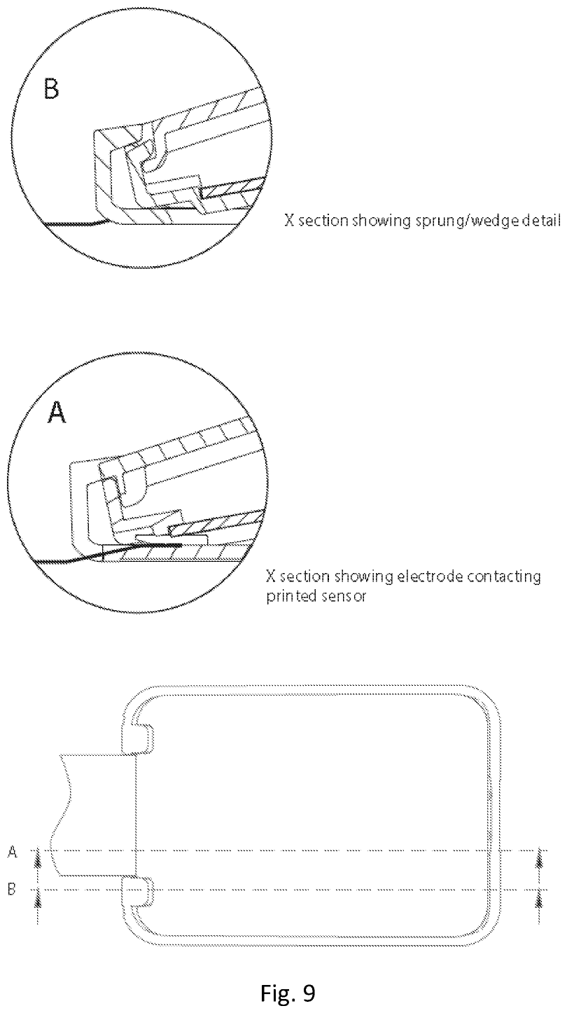

FIGS. 8 and 9 show magnified cross-sectional views of the inner 200 and outer 100 housings as the system is rotated closed. The jaws 115 are formed of resilient material. They therefore provide a spring action to further urge the inner housing 200 towards the base 110 of the outer housing 100 to clamp system around the substrate 300.

When fully inserted into the outer housing, the height of the front end of the inner housing 200 is slightly larger than the internal height of each jaw 115. This causes the jaws 115 to flex outwards slightly as the inner housing 200 is rotated towards the base 110 of the outer housing 100. In the present embodiment, the outer housing 100 is formed of moulded plastic that is resilient to flexing. Accordingly, the jaws 115 apply a resistive force to oppose the flexing. This provides additional clamping force to further improve the mechanical and electrical connection between the two sets of contacts.

The embodiments described above make use of the rotational camming action to provide a strong electrical and mechanical connection between one or more contacts on a PCB and one or more corresponding contacts on a flexible substrate. This allows more complicated circuitry to be easily and effectively connected to an inexpensive and disposable printed sensor. The flexible substrate is clamped into position between the inner housing and the base of the outer housing.

Alternative embodiments make use of the similar clamping action; however, connection is made to one or more contacts that form part of the base of the outer housing. That is, one or more electrodes may be printed or otherwise deposited onto the base of the outer housing, and one or more electrodes of the inner housing may be urged against one or more corresponding electrodes of the outer housing as discussed herein. In other words, the substrate upon which the one or more electrodes/contacts are deposited/located may be integrated into the base of the outer housing (or vice versa). This can be advantageous where circuitry is printed or otherwise deposited onto a solid substrate.

For instance, circuitry (e.g. the interdigitated tracks discussed above) may be located on or in a solid object, such as furniture, with the outer housing being integrated into or secured on to the object itself. The PCB may therefore be connected to circuitry printed onto the object, and may be easily removed after use. This means that the circuitry in the PCB may be more easily and efficiently recycled using electronic recycling techniques, whilst the object itself can be recycled using traditional techniques.

Where connection is made to electrodes printed onto the base of the outer housing, the base itself may be a surface of a solid object (such as the underside of some furniture) whilst the jaws and side and rear walls of the outer housing may be secured to said surface, e.g. via screws or other securing means. Alternatively, the outer housing may be milled, cut away, moulded or otherwise formed out of the object itself.

Whilst the embodiments discussed above include two jaws, alternative embodiments make use of one or more jaws. Each jaw can be considered to be a biasing member forming a cavity for receiving a front end of the inner housing.

Whilst the above embodiments make use of one or more a resilient jaws, in alternative embodiments the one or more jaws are non-resilient. The wedge-shaped cavity within each jaw can still provide the downward force required to urge the contacts together as the inner housing is urged into each jaw. In this case the inner housing may be biased or otherwise continually urged into the one or more jaws, for instance, via one or more springs or other biasing members.

Alternatively, each jaw may be resilient; however, in this case each jaw need not form a wedge-shaped cavity. Instead, the upper surface of the cavity may run parallel to the base of the inner housing. In this case, the internal height of the jaw is less than the height of the front end of the inner housing. The resilience of the jaw provides a downward force as the inner housing is rotated into the jaw.

Whilst the above embodiments describe how the inner housing may be rotated into the one or more jaws, alternative embodiments make use of a linear sliding action. In this case, the opening of each jaw has a height that is larger than the height of front end of the inner housing. This allows the inner housing to be slid into the jaw before making contact with the downward sloping upper surface of the jaw which provides the downward clamping force.

The above embodiments describe the use of an inner housing for housing a PCB. This provides the advantage that the housing provides structural support to allow the contacts to be urged together without risk of breaking the PCB. Furthermore, the additional height provided by the housing increases the torsional force provided as the inner housing is rotated within the one or more jaws. Nevertheless, in alternative embodiments the PCB itself may be directly inserted into the one or more jaws to urge the one or more contacts of the PCB against one or more corresponding contacts on the substrate. Alternatively, the one or more contacts, and the corresponding secretary of the PCB, may be integrated within the inner housing without the use of a PCB, for instance via soldering and wires.

While certain arrangements have been described, the arrangements have been presented by way of example only, and are not intended to limit the scope of protection. The inventive concepts described herein may be implemented in a variety of other forms. In addition, various omissions, substitutions and changes to the specific implementations described herein may be made without departing from the scope of protection defined in the following claims.

1. An electrical connector system suitable for electrically connecting a first electrode to a second electrode printed onto a substrate, the system comprising:
a male connector comprising the first electrode located on a base of the male connector; and
a female connector comprising a coupling portion forming a cavity with an opening into which the first end of the male connector may be received, the coupling portion having one or more biasing surfaces that each oppose a base of the female connector;
wherein the electrical connector system is configured such that when the male connector is urged into the coupling portion, the first electrode is urged towards the base of the female connector by the one or more biasing surfaces to form an electrical connection between the first electrode and the second electrode positioned between the base and the first end of the male connector.

2. The system of claim 1 wherein each of the one or more biasing surfaces is angled relative to the base such that the internal height of the cavity decreases from the opening towards a rear portion of the cavity.

3. The system of claim 1 wherein the female connector comprises a substrate receiving section configured to receive the substrate upon which the second electrode is printed and wherein the system is configured to clamp the substrate between the base and the first electrode when the male connector is urged into the coupling portion.

4. The system of claim 3 wherein the receiving section comprises a substrate holder that is configured to receive and hold the substrate in an interference fit prior to the male connector being received into the female connector.

5. The system of preceding claim 1 wherein the second electrode is incorporated into a flexible strip for insertion between the base and the first electrode.

6. The system of claim 1 wherein the base forms part of the substrate and wherein the second electrode is printed onto the base.

7. The system of claim 1 wherein the coupling portion is resilient and configured to be deflected at least partially when the first end is urged into the coupling portion thereby urging the first electrode against the base of the female connector.

8. The system of claim 1 wherein the female connector comprises a releasable locking mechanism configured to releasably secure the male connector into position in the female connector once the male connector has been urged into the coupling portion to secure the first electrode against the second electrode.

9. The system of claim 1 wherein for at least a portion of the cavity, the internal height of the cavity is less than a thickness of the first end of the male connector.

10. The system of claim 1 wherein the female connector comprises housing including a wall that opposes the coupling portion, wherein a distance between the coupling portion and the wall is substantially the same as a length of the male connector from the first end of the male connector to a second end of the male connector that is opposite to the first end, and wherein the system is configured such that the first electrode is urged towards the base of the female connector in response to the first end of the male connector being inserted into the coupling portion at an angle to the base of the female connector and being rotated towards the base of the female connector.

11. The system of claim 10 wherein the male connector comprises a sloped rear wall located at the second end of the male connector and configured to contact the wall of the female connector when the male connector is rotated towards the base of the female connector to urge the male connector further into the coupling portion.

12. The system of claim 1 wherein the first electrode of the male connector comprises two surfaces joined by an edge that is configured to contact the second electrode as the male connector is urged into the coupling portion.

13. The system of claim 1 wherein the first electrode is formed on a printed circuit board housed within the male connector and exposed at least at the first electrode.

14. The system of claim 13 wherein the male connector comprises a plurality of first electrodes formed on the printed circuit board, proximal to the first end of the male connector, wherein solder resist is removed from between the contacts to improve connection with one or more corresponding second electrodes positioned between the base and the first end of the male connector.

15. The system of claim 1 wherein the male connector comprises one or more indentations for receiving one or more protrusions from the coupling portion.

16. A male connector configured for use in an electrical connector system suitable for electrically connecting a first electrode to a second electrode printed onto a substrate, wherein:
the male connector comprises a first electrode located on a base of the male connector;
the male connector is configured for use with a female connector of the electrical connector system, wherein the female connector comprises a coupling portion forming a cavity with an opening into which the first end of the male connector may be received, the coupling portion having one or more biasing surfaces that each oppose a base of the female connector; and
the male connector is configured such that when the male connector is urged into a coupling portion of the female connector, the first electrode is urged towards the base of the female connector by the one or more biasing surfaces to form an electrical connection between the first electrode and the second electrode positioned between the base and the first end of the male connector.

17. A female connector configured for use in an electrical connector system suitable for electrically connecting a first electrode to a second electrode printed onto a substrate, wherein:
the female connector comprises a coupling portion forming a cavity with an opening into which a first end of a male connector may be received, the coupling portion having one or more biasing surfaces that each oppose a base of the female connector of; and
the female connector is configured such that when a male connector is urged into the coupling portion, a first electrode located on a base of the male connector is urged towards the base of the female connector by the one or more biasing surfaces to form an electrical connection between the first electrode and the second electrode positioned between the base and the first end of the male connector.
